(19) United States
(12) Patent Application Publication
(10) Pub. No.: US 2026/0156760 A1
(43) Pub. Date: Jun. 4, 2026

(54) Effective Enclosure Surface Features Design to Optimize Touchable Temperature for Power Adapter Devices

(71) Applicant: Flex Ltd., Singapore (SG)

(72) Inventors: Yung You Lin, New Taipei City (TW); Hung Cheng Chang, New Taipei City (TW); Lien Jin Chiang, New Taipei City (TW)

(73) Assignee: Flex Ltd., Singapore (SG)

(21) Appl. No.: 18/968,875

(22) Filed: Dec. 4, 2024

(51) Int. Cl. H05K 5/02; H02M 7/00

(52) U.S. Cl. CPC H05K 5/0217; H02M 7/003; H05K 5/0211

(57) ABSTRACT

A housing for a power device includes a rigid and thermally non-conductive casing comprising at least two outer surfaces. Each of the at least two outer surfaces includes a plurality of surface features that extend between opposing edges of a respective outer surface. Dimensions of the plurality of surface features prevent a user from touching of a plurality of recessed surfaces recessed from the plurality of surface features when the user grips the casing by the at least two outer surfaces.

### FIELD

The present disclosure is generally directed to power device housings, in particular, power device housings with surface features.

### BACKGROUND

High density power devices, such as power supplies, chargers, and adapters, generate significant heat which presents various challenges internal to and external to the power device.

### BRIEF DESCRIPTION OF THE DRAWINGS

FIG. 1 illustrates components of a power device according to at least one example embodiment.

FIG. 2 illustrates a first design for a housing of a power device according to at least one example embodiment.

FIG. 3 illustrates temperature performance of the first design according to at least one example embodiment.

FIG. 4 illustrates a second design for a housing of a power device according to at least one example embodiment.

FIG. 5 illustrates temperature performance of the second design according to at least one example embodiment.

FIG. 6 illustrates a third design for a housing of a power device according to at least one example embodiment.

FIG. 7 illustrates a fourth design for a housing of a power device according to at least one example embodiment.

FIG. 8 illustrates example dimensions for surface features and/or for recesses of a housing of a power device according to at least one example embodiment.

### DETAILED DESCRIPTION

The power device/adapter/charger market is seeking new products with smaller and/or narrower outside dimensions. High density compact design for power supplies, adapters, and chargers are desirable due to their smaller size but experience density-related challenges, such as those related to heat generated by the device. For example, heat generated by the power device may cause the housing or enclosure of the power device to become unsafe to touch and/or exceed safety requirements or standards (e.g., IEC 60950, IEC 62368, and/or the like).

Example embodiments propose an insulative surface feature design on a high density power device to deal with problems related to excessive surface temperatures of the power device's housing. Power device housing designs according to example embodiments may prevent user contact with high temperature outer surfaces of the housing and/or enhance heat transfer performance for more effective cooling of the power device. A power device housing design according to example embodiments may increase surface area of the housing to enhance thermal cooling performance (both convection and radiation heat transfer). In some examples, a housing includes a casing with a plurality of surface features on at least two surfaces of the casing. Gaps and recesses created by the surface features are large enough to have a cooling effect but small enough to prevent user contact with higher temperature recessed surfaces.

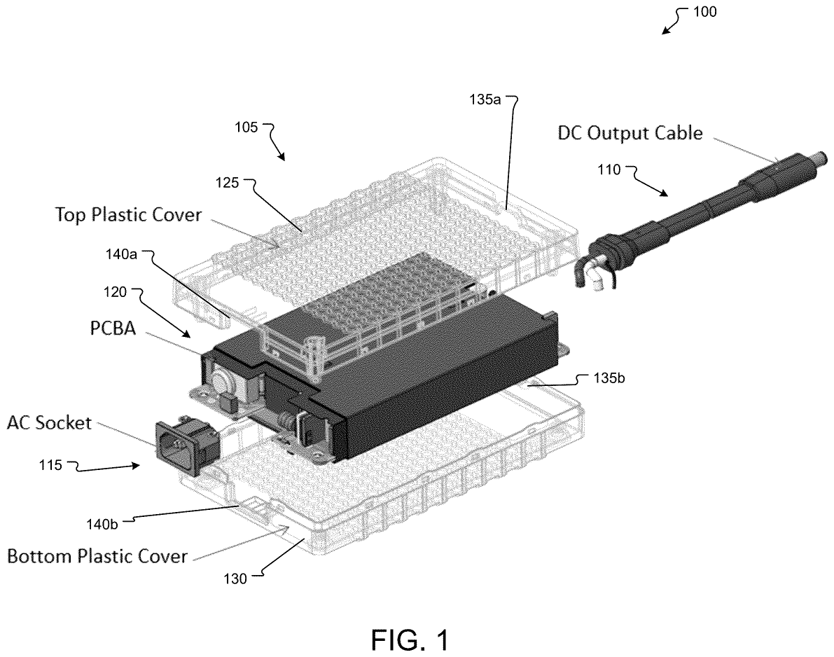

FIG. 1 illustrates power device 100 that includes a housing 105, a cable 110, a socket 115, and a power converter 120 electrically connected to the cable 110 and the socket 115. In general, the power device 100 may function as a power supply, a power adapter, or a charger for providing power to an external device (not shown), and thus, the power converter 120 may be designed to convert an input power signal to an output power signal having one or more different characteristics than the input power signal (e.g., different voltage level, different current level, different current type (AC vs. DC), different duty ratio, different waveforms, and/or the like).

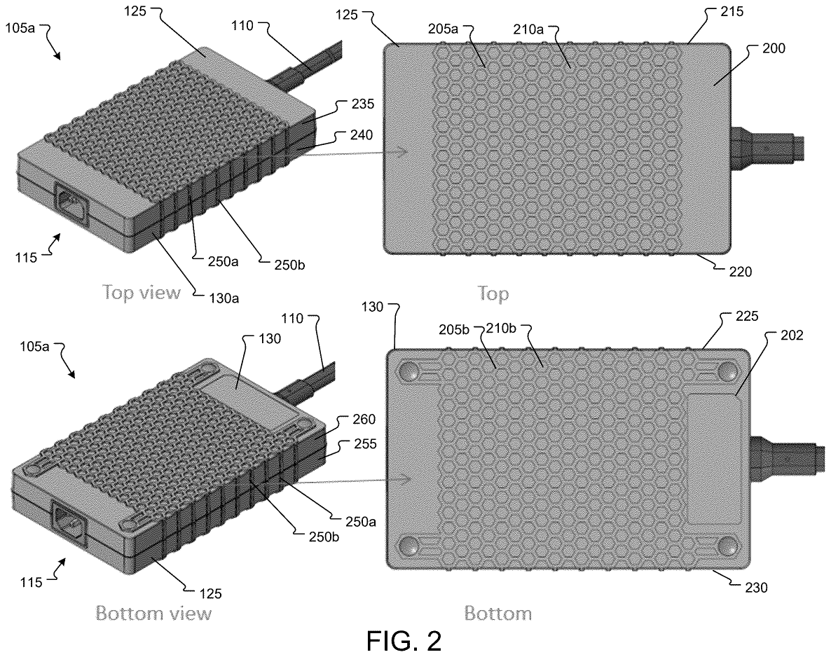

The housing 105 may comprise a single-part or multi-part casing. The housing in FIG. 1 is rectangular in shape but example embodiments are not limited thereto and any suitable shape may be used. The example in FIG. 1 and discussed herein with reference to other figures shows a housing 105 with a two-part casing that includes a top cover 125 and a bottom cover 130 which are securable together (e.g., with screws, with adhesive, by snap fit, and/or the like) to enclose an area that accommodates the power converter 120, the cable 110, and the socket 115. The casing of the housing 105 may be formed from a rigid and thermally (and electrically) non-conductive material, such as hard plastic or other suitable material for housing the aforementioned components of the power device 100. Details of the housing 105 are discussed in more detail below with reference to FIGS. 2-8 but should be generally understood to include a casing with at least two outer surfaces, where each of the at least two outer surfaces includes a pattern of a plurality of surface features that extend between opposing edges of a respective outer surface. As described herein, dimensions of the plurality of surface features prevent a user from touching of a plurality of recessed surfaces that are recessed from the plurality of surface features when the user grips the casing by the at least two outer surfaces.

The cable 110 and the socket 115 may have form factors suitable for the type of power signals being handled by the power device 100 and the type of connection to external devices (e.g., the source of the input power signals and the receiver of the output power signals). FIG. 1 illustrates an example where the socket is an AC socket (e.g., a two or three prong socket) for receiving AC power signals and the cable 110 is a DC output cable for outputting DC power signals. However, example embodiments are not limited thereto and the socket 115 and/or the cable 110 may have different form factors depending on design or application. For example, the cable 110 may be substituted for a socket or other suitable connection that connects to an external device that receives the output power signals from the power device 100. Similarly, the socket 115 may be substituted for a cable or other suitable connection that connects to an external device that provides the input power signals.

The power converter 120 may convert an input power signal into an output power signal. The input power signal may be an alternating current (AC) signal or a direct current (DC) signal and the output power signal may be an AC signal or a DC signal. Depending on the type of input and output power signals, the power converter 120 may be an AC-AC converter, an AC-DC converter, a DC-DC converter, or a DC-AC converter. The power converter 120 may include electrical and/or mechanical components suitable for converting an input power signal into an output power signal. Such components may include a rectifier circuit, an inverter circuit, a boost circuit, a buck circuit, and/or the like. In some examples, the power converter 120 is capable of two-way power conversion such that, in some cases, the socket 115 is an input for inputting power signals and the cable 110 is an output for outputting power signals while, in other cases, the cable 110 is an input for inputting power signals and the socket 115 is an output for outputting power signals. In some examples, like that shown in FIG. 1, the power converter 120 is included in a Printed Circuit Board Assembly (PCBA) along with one or more other electrical and/or mechanical components (e.g., heat sinks, power controllers, gate drivers, signal generators, and/or the like).

Still with reference to FIG. 1, the top (or first) cover 125 includes a first end including a first notch 135a for accommodating the cable 110 of the power device 100, and a second end opposite the first end and including a second notch 140a for accommodating the socket 115 of the power device. Meanwhile, the bottom (or second) cover 130 includes a first end including a first notch 135b that aligns with the first notch 135a of the first cover 125 when the first cover 125 is secured to the second cover 130 to thereby accommodate the cable 110 in the first notches 135a and 135b. The cover 130 may further comprise a second end opposite the first end of the second cover 130 and which includes a second notch 140b that aligns with the second notch 140a of the first cover 125 when the first cover 125 is secured to the second cover 130 to thereby accommodate the socket 115 in the second notches 140a and 140b. In some examples, only one of the covers 125 and 130 comprises suitable notches for the cable 110 and socket 115 while the other one of the covers remains notch-less.

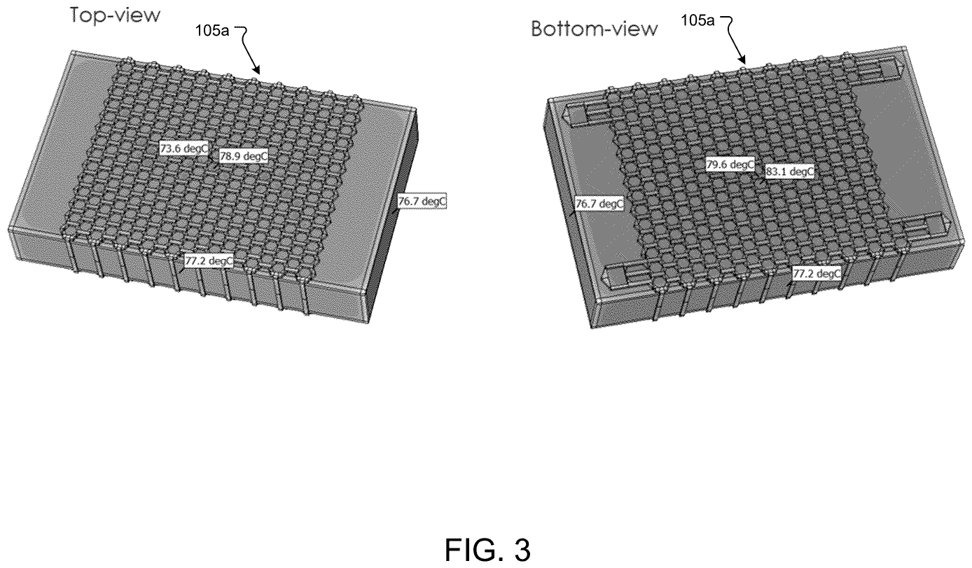

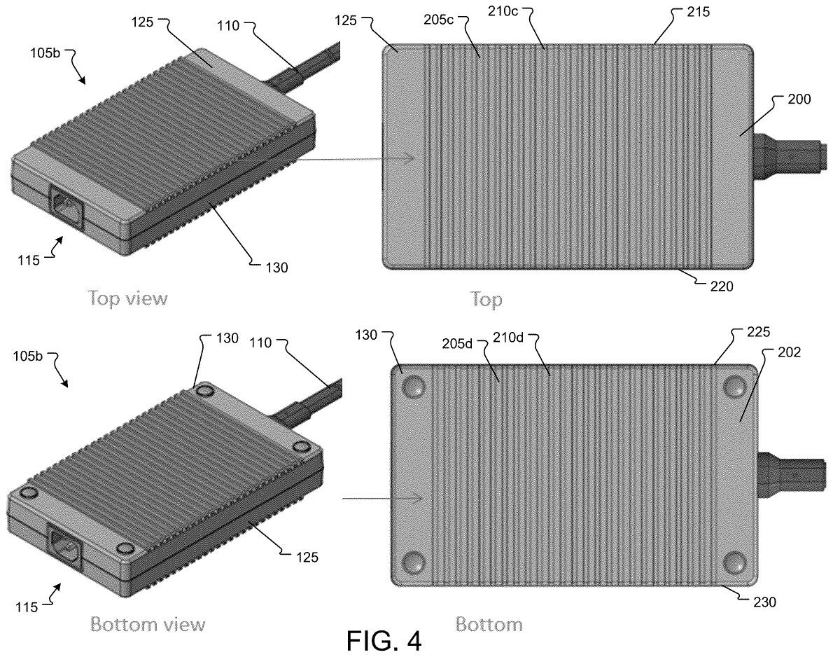

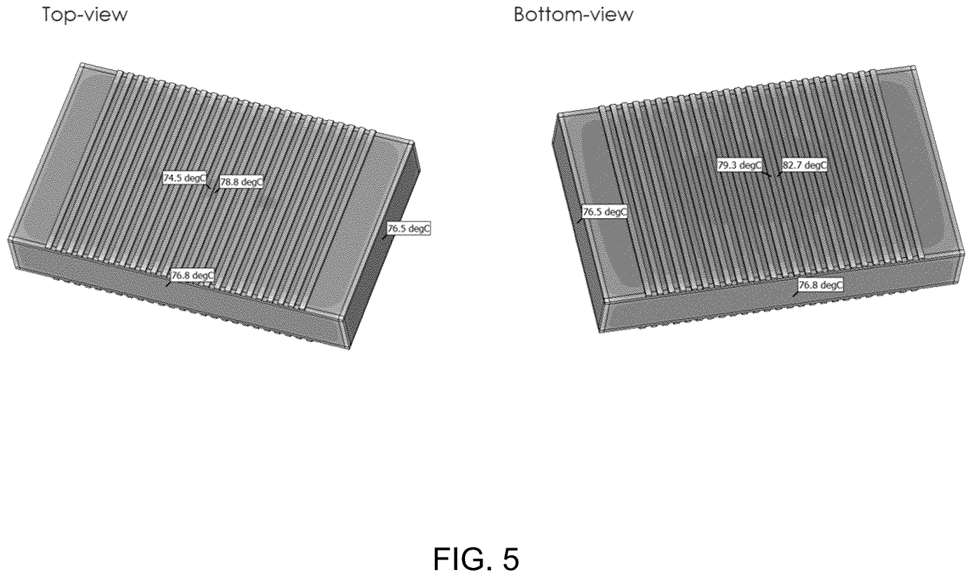

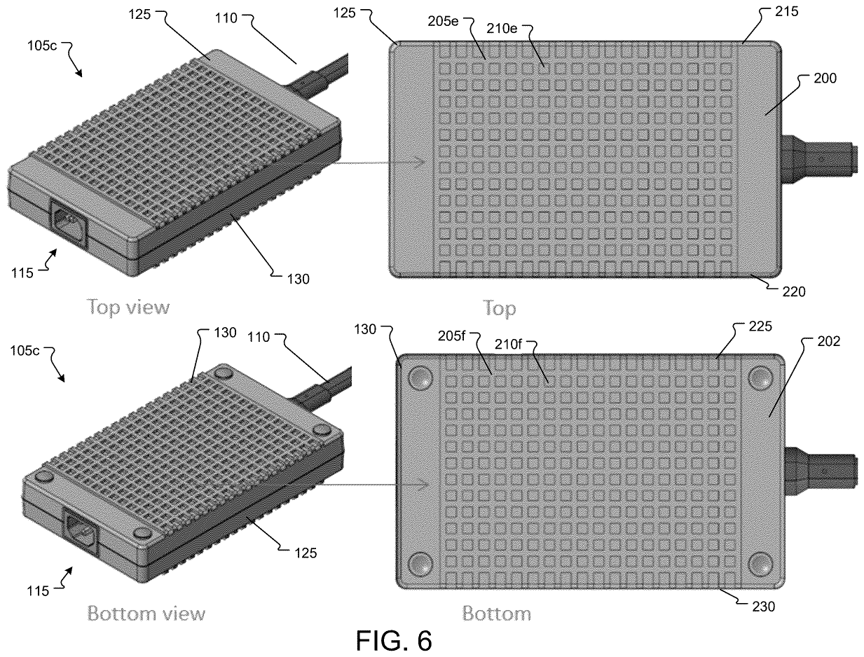

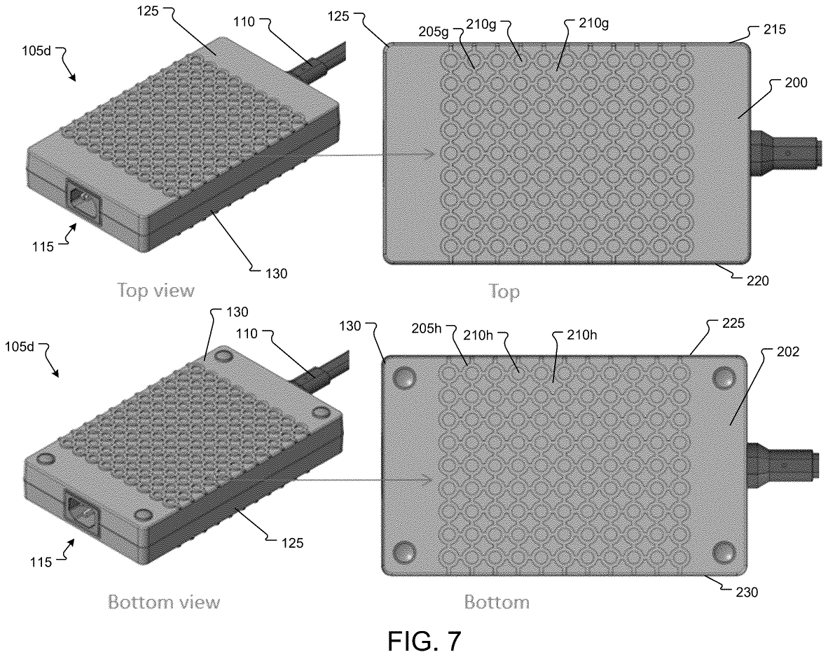

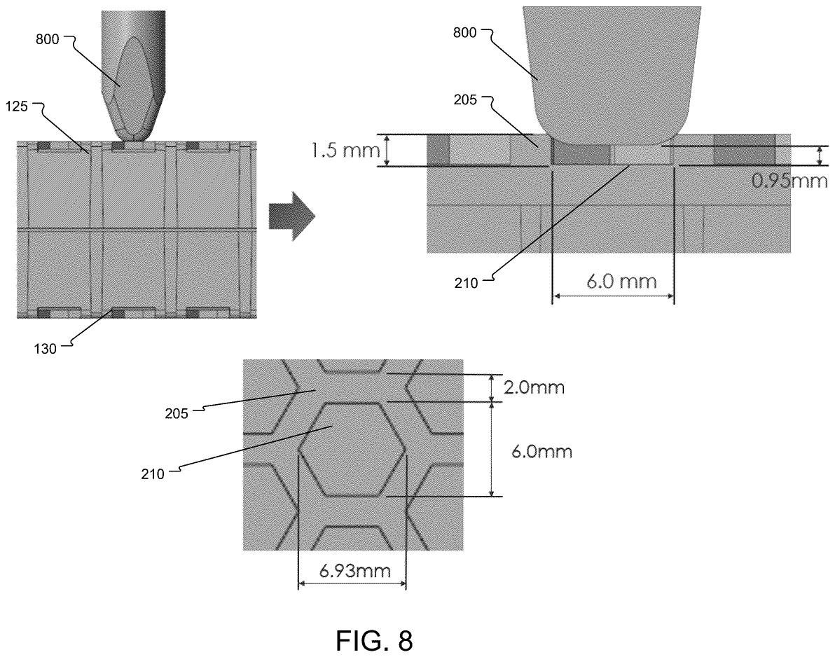

Designs for the housing 105 will now be discussed with reference to FIGS. 2-8, beginning with FIG. 2 which illustrates a first design for a housing 105a of a power device according to at least one example embodiment. FIG. 3 illustrates temperature performance of the first design according to at least one example embodiment. FIG. 4 illustrates a second design for a housing 105b of a power device according to at least one example embodiment. FIG. 5 illustrates temperature performance of the second design according to at least one example embodiment. FIG. 6 illustrates a third design for a housing 105c of a power device according to at least one example embodiment. FIG. 7 illustrates a fourth design for a housing 105d of a power device according to at least one example embodiment. FIG. 8 illustrates example dimensions for the surface features and/or recesses of a housing of a power device according to at least one example embodiment.

As may be appreciated, FIGS. 2-7 show the same elements of a power device aside from differences in the pattern of surface structures and recessed surfaces, with FIGS. 2-3 showing a first design for surface features 205a/b and recessed surfaces 210a/b, FIGS. 4-5 showing a second design for surface features 205c/d and recessed surfaces 210c/d, FIG. 6 showing a third design for surface features 205e/f and recessed surfaces 210e/f, and FIG. 7 showing a fourth design for surfaces features 205g/h and recessed surfaces 210g/h. Meanwhile, the dimensions (e.g., height of surface features and relative dimensions) shown and described with reference to surface features and recessed surfaces in FIG. 8 may be applied to the other figures. In any event and for all housing designs, the plurality of surface features 205 on outer surfaces 200 and 202 cover more than 80% of each respective outer surface.

FIG. 2 illustrates housing 105a with a casing that comprises a rigid first cover 125 including a first outer surface 200 having a first plurality of surface features 205a that extend between opposing edges 215 and 220 of the first outer surface 200. As may be appreciated, the plurality of surface features 205a take the form of protrusions that project from the surface 200 so as to be raised compared to a plurality of recessed surfaces 210a. The surface features 205a may have substantially the same properties (height, width, shape, length), with the term “substantially” being used herein to account for manufacturing variations that are within acceptable tolerances. The recessed surfaces 210a may correspond to parts of the surface 200 that are not raised. Stated another way, the surface 200 and recessed surfaces 210a are in a same plane while the surface features 205a are raised relative to thereto.

The casing of the housing 105a may further comprise a rigid second cover 130 securable to the first cover 125 to form an enclosed area for accommodating the power converter 120. As with the first cover 125, the second cover 130 includes a second outer surface 202 having a second plurality of surface features 205b that extend between opposing edges 220 and 225 of the second outer surface 202. The plurality of second surface features 205b have substantially the same properties (shape and dimensions) and the surface features 205a. Likewise, recessed surfaces 210b of the second cover 130 have substantially the same properties (shape and dimensions) as the recessed surfaces 210a.

As may be appreciated, FIGS. 4, 6, and 7 illustrate housings 105b, 105c, and 105d, respectively, and each figure includes the same elements as in FIGS. 1 and 2 except that the housings 105b, 105c, and 105d comprise different surface features 205 and recessed surfaces 210 compared to FIGS. 1 and 2. For example, the plurality of surface features 205c in FIG. 3 are linear ribs or ridges that extend between the opposing edges 215/220 and 225/230 of each outer surface 200 and 202. Meanwhile, the recessed surfaces 210c in FIG. 3 are also linear so as to form trenches that extend between the opposing edges of each outer surface 200 and 202.

FIGS. 2, 6, and 7 comprise surface features 205 that are interconnected on each outer surface 200 and 202. As shown in these figures, the surface features 205a/b, 205e/f, and 205g/h are interconnected so as to form a lattice pattern. The lattice pattern may comprise or form interconnected shapes. The interconnected shapes may be hexagons, such as in FIG. 2, rectangles as in FIG. 6, or circles as in FIG. 7. Each shape within each lattice pattern may have substantially the same dimensions.

As shown in FIG. 2, for example, sides 235 and 255 of the cover 125 may comprise additional surface features 250a, shown in FIG. 2 as linear ridges or ribs that interconnect with surface features 205a on outer surface 200. Similarly, sides 240 and 260 of cover 130 may comprise additional surface features 250b, shown in FIG. 2 as linear edges of ribs that interconnect with surface features 205b on surface 202. Here, it should be appreciated that the sides of covers 125 and 130 may include the same or similar surface features as on outer surfaces 200 and 202 instead of or in additional the illustrated ridges or ribs. The same or similar surface features may be applied to the sides of covers 125 and 130 in the designs shown in FIGS. 4, 6, and 7.

As may be appreciated, dimensions of the surface features 205 in each figure are such that a user is prevented from touching the plurality of recessed surfaces. Indeed, FIG. 8 illustrates an example where dimensions of the surface features 205 prevent a user 800 (e.g., a finger of a user) from touching of the plurality of recessed surfaces 210 recessed from the surface features 205 when the user grips the housing 105 by the first and second outer surfaces 200 and 202. For example, a user's finger at maximum depth within a recess created by a surface feature 205 is still 0.95 mm away from a recessed surface 310. As shown in FIG. 8, a height of each surface feature 205 is about 1.5 mm, and a width of each surface feature 205 is about 2.0 mm. A maximum dimension of each recessed surface 210 is about 7.0 mm, such as 6.93 mm for a recessed surface width and 6.0 mm for a recessed surface length in FIG. 8. In addition, a ratio of a maximum dimension of each recessed surface 210 to a height of each surface feature 205 is less than 4.70, such as 4.62 in FIG. 8 (6.93 mm:1.5 mm). Although FIG. 8 shows dimensions for the first housing design in FIGS. 2 and 3, it should be appreciated that the other designs in FIGS. 2-7 may have the same maximum dimension limitations, the same surface feature height and width, and the same ratio(s) between dimensions as in FIG. 8.

With reference to FIGS. 2-7, the plurality of surface features on each outer surface 200 and 202 may cover enough of the outer surfaces so as to ensure a user can easily grip the housing 105 in an area that has the surface features. In some examples, then, more than 80% of the respective outer surface is covered by surface features without covering an entirety of each outer surface. For example, as shown in the figures, each outer surface 200 and 202 may comprise smooth areas at both ends of each outer surface where no surface features are formed, which may simplify manufacturing. Speaking of manufacturing, the surface features illustrated in FIGS. 2-7 may be formed by suitable process, such as by a molding process or an imprinting process when forming each cover 125 and 130.

As noted herein, the and with reference to FIGS. 3 and 5, surface features according to example embodiments are useful for reducing the temperature of surfaces that may come into contact with a user's fingers or hand when maneuvering the power device 100. For example, a temperature difference between the plurality of recessed surfaces 210 and the plurality of surface features 205 for anyone of the designs may be greater than 4.1%, such as between 4.1% and 6.8%. FIGS. 3 and 5 illustrate examples that used thermal simulation software (e.g., FLOTHERM) to model a 600 W power device with 95.1% efficiency (30.9 W power dissipation) at 25 deg.C ambient. Table 1 shows the results of the simulation compared to a related art design housing that has no surface features.

TABLE 1

| | Related art | | |
|---|---|---|---|
| | design | Honeycomb | Rectangular |
| | (no surface | Features | Rib Features |
| Location | features) | (FIG. 2) | (FIG. 4) |
| Top Touchable Surface | 78.3 | 73.6 | 74.5 |
| (deg. C.) | | | |
| Top Surface-recess | — | 78.9 | 78.8 |
| (deg. C.) | | | |
| Bottom Touchable Surface | 82.3 | 79.6 | 79.3 |
| (deg. C.) | | | |
| Bottom Surface-recess | — | 83.1 | 82.7 |
| (deg. C.) | | | |
| Left/Right Surface | 74.9 | 77.2 | 76.8 |
| (deg. C.) | | | |
| AC/DC Surface (deg. C.) | 74.5 | 76.7 | 76.5 |
| Max. Touchable Surface | 57.3 | 54.6 | 54.3 |
| Temp Rise from Ambient | | | |
| (deg. C.) | | | |
| Improvement in Temp Rise | — | 4.7% | 5.2% |
| from Ambient (%) | | | |

As noted herein, systems and methods according to example embodiments solve various problems including but not limited to: high surface temperatures of a power device housing, safety risks related to the high surface temperatures, and/or complications with cooling the power device.

The phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more,” and “at least one” can be used interchangeably herein. It is also to be noted that the terms “comprising,” “including,” and “having” can be used interchangeably.

Any one or more of the aspects/embodiments as substantially disclosed herein.

Any one or more of the aspects/embodiments as substantially disclosed herein optionally in combination with any one or more other aspects/embodiments as substantially disclosed herein.

One or more means adapted to perform any one or more of the above aspects/embodiments as substantially disclosed herein.

Example embodiments may be configured as follows:

(1) A housing for a power device, comprising:
a rigid and thermally non-conductive casing comprising at least two outer surfaces, each of the at least two outer surfaces including a plurality of surface features that extend between opposing edges of a respective outer surface, wherein dimensions of the plurality of surface features prevent a user from touching of a plurality of recessed surfaces recessed from the plurality of surface features when the user grips the casing by the at least two outer surfaces.

(2) The housing of (1), wherein the casing comprises:
a first cover including a first outer surface of the at least two outer surfaces; and a second cover securable to the first cover to form an enclosed area for accommodating the power device, the second cover including a second outer surface of the at least two outer surfaces.

(3) The housing of one or more of (1) to (2), wherein the first cover includes:
a first end including a first notch for accommodating a cable of the power device; and a second end opposite the first end and including a second notch for accommodating a socket of the power device.

(4) The housing of one or more of (1) to (3), wherein the second cover includes:
a first end including a first notch that aligns with the first notch of the first cover when the first cover is secured to the second cover to thereby accommodate the cable in the first notches; and
a second end opposite the first end of the second cover and including a second notch that aligns with the second notch of the first cover when the first cover is secured to the second cover to thereby accommodate the socket in the second notches.

(5) The housing of one or more of (1) to (4), wherein the of the plurality of surface features covers more than 80% of the respective outer surface.

(6) The housing of one or more of (1) to (5), wherein the plurality of surface features are linear ribs that extend between the opposing edges of the respective outer surface.

(7) The housing of one or more of (1) to (6), wherein the plurality of surface features are interconnected.

(8) The housing of one or more of (1) to (7), wherein the plurality of surface features form a lattice pattern.

(9) The housing of one or more of (1) to (8), wherein the lattice pattern comprises interconnected shapes.

(10) The housing of one or more of (1) to (9), wherein the interconnected shapes comprise circles, rectangles, or hexagons.

(11) The housing of one or more of (1) to (10), wherein a maximum dimension each recessed surface is about 7 mm.

(12) The housing of one or more of (1) to (11), wherein a height of each surface feature is about 1.5 mm.

(13) The housing of one or more of (1) to (12), wherein a width of each surface feature is about 2.0 mm.

(14) The housing of one or more of (1) to (13), wherein a ratio of a maximum dimension of each recessed surface to a height of each surface feature is less than 4.7.

(15) The housing of one or more of (1) to (14), wherein a temperature difference between the plurality of recessed surfaces and the plurality of surface features is greater than 4.1%.

(16) A system, comprising:
a power device to convert an input signal to an output signal; and
a housing that houses the power device, the housing comprising a rigid and thermally non-conductive casing comprising at least two outer surfaces, each of the at least two outer surfaces including a plurality of surface features that extend between opposing edges of a respective outer surface, wherein dimensions of the plurality of surface features prevent a user from touching of a plurality of recessed surfaces recessed from the plurality of surface features when the user grips the casing by the at least two outer surfaces.

(17) The system of (16), wherein the input signal is an alternating current (AC) signal.

(18) The system of one or more of (16) to (17), wherein the output signal is a direct current (DC) signal.

(19) A housing for a power device, comprising:
a rigid first cover including a first outer surface having a first plurality of surface features that extend between opposing edges of the first outer surface;
a rigid second cover securable to the first cover to form an enclosed area for accommodating the power device, the second cover including a second outer surface having a second plurality of surface features that extend between opposing edges of the second outer surface, wherein dimensions of the first and second pluralities of surface features prevent a user from touching of a plurality of recessed surfaces recessed from the first and second pluralities of surface features when the user grips the housing by the first and second surfaces.

(20) The housing of (19), wherein the first cover and the second cover each include:
a first notch for accommodating a cable of the power device; and
a second notch for accommodating a socket of the power device.

What is claimed is:

1. A housing for a power device, comprising:
a rigid and thermally non-conductive casing comprising at least two outer surfaces, each of the at least two outer surfaces including a plurality of surface features that extend between opposing edges of a respective outer surface, wherein dimensions of the plurality of surface features prevent a user from touching of a plurality of recessed surfaces recessed from the plurality of surface features when the user grips the casing by the at least two outer surfaces.

2. The housing of claim 1, wherein the casing comprises:
a first cover including a first outer surface of the at least two outer surfaces; and
a second cover securable to the first cover to form an enclosed area for accommodating the power device, the second cover including a second outer surface of the at least two outer surfaces.

3. The housing of claim 2, wherein the first cover includes:
a first end including a first notch for accommodating a cable of the power device; and
a second end opposite the first end and including a second notch for accommodating a socket of the power device.

4. The housing of claim 3, wherein the second cover includes:
a first end including a first notch that aligns with the first notch of the first cover when the first cover is secured to the second cover to thereby accommodate the cable in the first notches; and
a second end opposite the first end of the second cover and including a second notch that aligns with the second notch of the first cover when the first cover is secured to the second cover to thereby accommodate the socket in the second notches.

5. The housing of claim 1, wherein the of the plurality of surface features covers more than 80% of the respective outer surface.

6. The housing of claim 1, wherein the plurality of surface features are linear ribs that extend between the opposing edges of the respective outer surface.

7. The housing of claim 1, wherein the plurality of surface features are interconnected.

8. The housing of claim 7, wherein the plurality of surface features form a lattice pattern.

9. The housing of claim 8, wherein the lattice pattern comprises interconnected shapes.

10. The housing of claim 9, wherein the interconnected shapes comprise circles, rectangles, or hexagons.

11. The housing of claim 1, wherein a maximum dimension each recessed surface is about 7 mm.

12. The housing of claim 11, wherein a height of each surface feature is about 1.5 mm.

13. The housing of claim 12, wherein a width of each surface feature is about 2.0 mm.

14. The housing of claim 1, wherein a ratio of a maximum dimension of each recessed surface to a height of each surface feature is less than 4.7.

15. The housing of claim 1, wherein a temperature difference between the plurality of recessed surfaces and the plurality of surface features is greater than 4.1%.

16. A system, comprising:
a power device to convert an input signal to an output signal; and
a housing that houses the power device, the housing comprising a rigid and thermally non-conductive casing comprising at least two outer surfaces, each of the at least two outer surfaces including a plurality of surface features that extend between opposing edges of a respective outer surface, wherein dimensions of the plurality of surface features prevent a user from touching of a plurality of recessed surfaces recessed from the plurality of surface features when the user grips the casing by the at least two outer surfaces.

17. The system of claim 16, wherein the input signal is an alternating current (AC) signal.

18. The system of claim 17, wherein the output signal is a direct current (DC) signal.

19. A housing for a power device, comprising:
a rigid first cover including a first outer surface having a first plurality of surface features that extend between opposing edges of the first outer surface;
a rigid second cover securable to the first cover to form an enclosed area for accommodating the power device, the second cover including a second outer surface having a second plurality of surface features that extend between opposing edges of the second outer surface, wherein dimensions of the first and second pluralities of surface features prevent a user from touching of a plurality of recessed surfaces recessed from the first and second pluralities of surface features when the user grips the housing by the first and second surfaces.

20. The housing of claim 19, wherein the first cover and the second cover each include:
a first notch for accommodating a cable of the power device; and
a second notch for accommodating a socket of the power device.
